(19) United States
(12) Patent Application Publication
(10) Pub. No.: US 2025/0316952 A1
(43) Pub. Date: Oct. 9, 2025

(54) HETEROGENEOUSLY INTEGRATED OPTOELECTRONIC CHIP BASED ON OPTICAL THROUGH-SUBSTRATE VIA

(71) Applicant: Hangzhou Lightip Technologies Co., Ltd., Hangzhou (CN)

(72) Inventors: Jiasheng ZHAO, Hangzhou (CN); Jianjun HE, Hangzhou (CN)

(21) Appl. No.: 19/241,313

(22) Filed: Jun. 17, 2025

(30) Foreign Application Priority Data
Jun. 19, 2024 (CN) 202410792631.5

(51) Int. Cl. H01S 5/0239; H01S 5/0234; H01S 5/028

(52) U.S. Cl. CPC H01S 5/0239; H01S 5/0234; H01S 5/028

(57) ABSTRACT

The present invention discloses a heterogeneously integrated optoelectronic chip based on an optical through-substrate via (TSV), comprising multiple stacked optoelectronic chips based on the same or different types of substrates, each layer of optoelectronic chips having several optoelectronic devices, and at least one pair of optoelectronic chip layers are attached back-to-back and have an optical TSV with interlayer coupling structures at both ends, so as to establish optical interconnection between at least one pair of optoelectronic devices in different layers. The interlayer coupling structures include coupling gratings with high alignment tolerance, and a high-reflectivity metal film at a certain distance above the grating to achieve efficient unidirectional coupling. The invention solves the technical difficulties of III-V/silicon heterogeneous integration and 3D multi-chip stacking. It achieves interlayer connections through optical TSVs, enabling front electrodes of optoelectronic chips to be used for interconnection with electronic chips, avoiding the fabrication difficulty of electrical TSVs.

### CROSS-REFERENCE TO RELATED APPLICATIONS

This application claims the benefit of priority from Chinese Patent Application No. 202410792631.5 filed on Jun. 19, 2024. The content of the aforementioned application, including any intervening amendments thereto, is incorporated herein by reference in its entirety.

### TECHNICAL FIELD

The invention relates to the technical field of optoelectronic chips, particularly to a heterogeneously integrated optoelectronic chip based on Optical Through-Substrate Via.

### BACKGROUND OF THE PRESENT INVENTION

Currently, data centers/intelligent computing systems are composed of thousands of servers connected through fiber optic networks. In addition to the core computing chips in servers, the high-speed optical switching interconnection network between a large number of computing chips or servers is the key to improving the overall computing power of intelligent computing/supercomputing systems and efficiently utilizing them. In order to reduce the size, energy consumption, and cost of intelligent computing system equipment, advanced wafer level packaging technology based on chiplets in the field of large-scale integrated circuits has been applied to optical chips and hybrid optoelectronic wafer level systems, including Through Silicon Via (TSV) and Re-Distribution Layer (RDL) technologies. This enables the front of the silicon photonic chip to be integrated with III-V lasers, while the back of the silicon photonic chip can be electrically interconnected and integrated with the computing chips employing TSV as an electrical through-substrate via.

There are currently three main technologies used in silicon-based III-V compound semiconductor hybrid integration:

One is the III-V/SOI (Silicon on Insulator) bonding technology based on evanescent wave coupling. Its drawback is its complex manufacturing process, mismatch between III-V wafer size and Si wafer size, and most of the III-V material in the bonding region is etched away and thus wasted. In addition, there are lattice mismatch and thermal expansion coefficient mismatch between III-V semiconductors and Si, resulting in yield and reliability issues.

The second method is to directly grow III-V quantum dot materials on silicon wafers. Its drawback is that a thick buffer layer and defect filtering layer need to be grown before growing quantum dots on silicon. This makes it difficult to use evanescent wave coupling between III-V waveguides and Si waveguides, and only butt coupling can be used. III-V gain materials need to be grown in etched grooves, and the growth conditions need to be precisely controlled, requiring more than 20 layers of masks and hundreds of processing steps. The laser performance and yield are difficult to control, and the cost is high.

The third is the end face coupling technology based on flip chip bonding. Its drawback is that the strong confinement of small mode field waveguides such as SOI makes it difficult to achieve the required alignment accuracy. In addition, for wafer level packaging, locally protruding III-V chips hinder the surface planarization of silicon photonic chips and also hinder the interconnection between SOI surface electrodes and electronic chips or interposers, which is incompatible with advanced wafer level CMOS packaging processes.

### SUMMARY OF THE PRESENT INVENTION

The purpose of the present invention is to provide a heterogeneously integrated optoelectronic chip based on optical through-substrate via. The concept of the optical through-substrate via (referred to as optical TSV) is proposed for 3D integration of multi-layer optoelectronic chips in wafer level on-chip systems, simultaneously addressing the technical challenges of silicon-based III-V heterogeneous integration and 3D multi-layer chip stacking interconnection. By utilizing advanced packaging technology for chiplet integration, the optical transceiver interconnect chips are integrated with GPU/NPUs and other electronic chips at the wafer level. This not only integrates the electrical-to-optical and optical-to-electrical conversions of GPU/NPU I/O ports inside the photonic chip, but also greatly improves chip integration level and reduces the system size. With the novel optical TSVs, optical signals travel through InP and Si substrates, achieving efficient and high tolerance optical coupling between III-V waveguide layers and SOI or SiN layers while avoiding flip-chip bonding between III-V chips and SiN/SOI chips. The front electrode layers of these two chips are thus reserved for electrical interconnection with the electronic chips or RDL or PCB, thus avoiding the use of conventional difficult-to-process electrical TSVs on silicon photonic chips.

To achieve the above objectives, the present invention provides a heterogeneously integrated optoelectronic chip based on Optical Through-Substrate Via, comprising a multi-layer stacked optoelectronic chip based on several substrates of the same or different types. Each layer of optoelectronic chip is provided with several optoelectronic devices and optical waveguides, and at least one pair of optoelectronic chips of different layers are each provided with an interlayer coupling structure. There is an optical through-substrate via between the interlayer coupling structure of the at least one pair of optoelectronic chips. The first layer of optoelectronic chip and the second layer of optoelectronic chip in the at least one pair of optoelectronic chips are attached back-to-back, that is, the back of the first substrate and the back of the second substrate are in contact or bonded to each other and the optical through-substrate via passes through at least two substrates. The first interlayer coupling structure in the first layer of optoelectronic chip based on the first substrate converts the light propagating along the optical waveguide in the plane of the first layer of optoelectronic chip into light propagating along the optical through-substrate via in the first substrate through reflection or diffraction mechanism. The second interlayer coupling structure within the second layer of the optoelectronic chip based on the second substrate converts the light propagating along the optical through-substrate via in the second substrate into light propagating along the optical waveguide in the plane of the second optoelectronic chip layer through reflection or diffraction mechanisms. The front electrode of the first layer of optoelectronic chip is electrically connected to external circuits such as the electronic driver chip, and the front electrode of the second layer of optoelectronic chip is flip-chip bonded to an interposer chip to achieve high-speed electrical interconnection with electronic drivers, computing chips, and switching chips. The interlayer signal transmission is achieved through the optical through-substrate via (TSV), thereby avoiding the traditional difficult-to-fabricate electrical TSV process.

Preferably, the first layer optoelectronic chip based on the first substrate comprises at least one of optical signal emitting devices, optical amplifying devices, optical modulators, optical detectors, and passive optical waveguide interconnect devices. The interlayer coupling structure of the optoelectronic chip in this layer is a coupling grating or a reflection mirror composed of a tilted etched surface;

The second layer optoelectronic chip based on the second substrate comprises at least one of passive optical waveguide interconnect devices, optical modulators, and optical signal receivers. The interlayer coupling structure of the optoelectronic chip in this layer is a coupling grating or a reflection mirror composed of a tilted etched surface.

Preferably, the first layer of optoelectronic chip is back-to-back coupled with the second layer of optoelectronic chip, and the back of the first substrate is in contact or bonded with the back of the second substrate. The contact surface of one or both substrates is smooth or coated with an optical anti-reflection film.

Preferably, the third layer of optoelectronic chip is positively coupled with the first layer of optoelectronic chip, and the back of the third substrate is in contact with the front of the first layer of optoelectronic chip. The back of the third substrate is smooth or coated with an optical anti-reflection film.

Preferably, the first substrate is InP, GaAs or compound semiconductor material, and the second substrate is Si, SiO2, quartz or organic substrate material.

Preferably, the first interlayer coupling structure is a chirped collimated grating, which couples the light to the optical through-substrate via as a parallel beam. The gradient grating coupling coefficient is obtained by optimizing the design of grating etching depth and gradient duty cycle, so that the light emitted to the optical through-substrate via has a certain optical field distribution, trimming the diffracted light field on the grating that exponentially decreases along the waveguide propagation direction into a shape close to Gaussian, resulting in a large and collimated beam size, satisfying the conditions of large alignment tolerance and high coupling efficiency.

Preferably, a layer of high reflection metal film is deposited on the upper surface of the chirped collimated grating as a metal reflector. The high reflection metal film is at a certain distance from the grating, so that the light directly diffracted by the chirped collimated grating to the optical through-substrate via can be constructively interfered with the light diffracted upward above the grating and then reflected by the high reflection metal film to the optical through-substrate via, resulting in the highest light intensity transmitted to the optical through-substrate via.

Preferably, the first interlayer coupling structure is an etched surface placed at a specific angle, allowing light incident from the waveguide to the etched surface to undergo total reflection and propagate through the substrate.

Preferably, the second interlayer coupling structure is a chirped focusing grating that focuses the optical signal received from the optical through-substrate via onto the optical signal receiving point on the second layer optoelectronic chip, and optimizes the grating etching depth and gradient duty cycle to achieve the highest coupling efficiency.

Preferably, a layer of high reflection metal film is deposited on the surface of the cladding of the chirped focusing grating as a metal reflector. The high reflection metal film is at a certain distance from the chirped focusing grating, so that the light directly diffracted from the optical through-substrate via to the optical signal receiving point by the chirped focusing grating is constructively interfered with the light transmitted through the grating, reflected by the high reflection metal film, and then diffracted by the chirped focusing grating to the optical signal receiving point, resulting in the strongest coupling of light to the optical signal receiving point.

The present invention adopts the above-mentioned heterogeneously integrated optoelectronic chip based on Optical Through-Substrate Via, which has the following advantages:

The heterogeneous integration and 3D interconnect scheme based on optical TSV proposed by the present invention has high flexibility and universality. Each chip or wafer can be manufactured separately using mature processes, and 3D heterogeneous integration and interlayer coupling can be performed after testing. Moreover, compared with other heterogeneous integration based on bonding methods, the bonding process is simpler and the alignment tolerance is larger, which can greatly improve the yield of heterogeneous integration and on-chip systems. Compared to the full wafer quantum dot epitaxial growth method, the solution of the present invention adopts mature processes, greatly reducing the complexity and difficulty of epitaxial and post-processing, greatly improving the utilization efficiency of InP epitaxial area, reducing the manufacturing difficulty of large-area wafer level interconnects, and thus significantly reducing costs. Moreover, through the interlayer interconnection of optical TSVs, the front electrode of SOI chips can be easily flip chip bonded with the interconnect substrate (Interposer), achieving high-speed electrical interconnection with electronic drivers, computing chips, and switching chips, avoiding the use of difficult traditional through-hole processes for electrical TSV on silicon photonic chips. The front electrode of the InP chip can also be conveniently used for direct electrical connection with external circuits such as electronic driver chips, without the need for fan out in expensive active silicon photonic chips.

Due to the strong flexibility and universality of the interlayer optical interconnect and three-dimensional heterogeneous integration through the substrate of the present invention, it can become a standard multifunctional optoelectronic integration platform, which can be used not only for heterogeneously integrated optoelectronic chips, but also for multi-layer stacked interconnect integration of computing chips with optical transceiver I/O ports.

The technical solution of the present invention will be further described in detail through the accompanying drawings and embodiments.

### BRIEF DESCRIPTION OF THE DRAWINGS

FIG. 1 is a schematic structural diagram of Embodiment 1.

FIG. 2 is a top view of the coupling grating on an InP chip in Embodiment 1, where P is the endpoint of the emitting optical waveguide.

FIG. 3 is a top view of a coupling grating on a silicon photonic chip in Embodiment 1, where Q is the endpoint of the receiving optical waveguide.

FIG. 4 is a schematic diagram of the structure of Embodiment 2.

FIG. 5 is a schematic diagram of the structure of Embodiment 3.

100. InP chip driver circuit board; 101. Packaging substrate; 102. Solder ball array; 103. Electrical through holes; 104. SiO2 layer; 105. Silicon waveguide layer; 106. SiN waveguide; 107. Silicon substrate; 108. Silicon substrate of SiN wafer; 109. Silicon substrate of SOI wafer; 110. InP substrate; 111. InP waveguide layer; 112. Motherboard PCB; 113. Intermediate interposer layer; 114. Optical signal input port; 115. Optical signal output port; 20. Power monitor; 30. Laser; 400. Interlayer coupling reflection surface on InP chip side; 401. Interlayer coupling grating on InP chip side; 402. Interlayer coupling grating 1 on silicon optical chip side; 411. Interlayer coupling grating 1 on SiN waveguide; 412. Interlayer coupling grating 2 on silicon optical chip side; 421. Interlayer coupling grating 2 on SiN waveguide; 422. Interlayer coupling grating 3 on silicon optical chip side; 50. Metal reflector; 500. Optical through-substrate via; 501. Optical through-substrate via 1; 502. Optical through-substrate via 2; 503. Optical through-substrate via 3; 60. High speed detector; 70. Silicon waveguide devices; 80. High speed modulator.

### DETAILED DESCRIPTION OF THE PRESENT INVENTION

In order to clarify the purpose, technical solution, and advantages of the embodiments of the present invention, the following will provide a clear and complete description of the technical solution in the embodiments of the present invention in conjunction with the accompanying drawings. Obviously, the described embodiments are a part of the embodiments of the present invention, not all of them. The components of the embodiments of the present invention described and illustrated in the accompanying drawings can be arranged and designed in various different configurations. The specific structure needs to be selected and determined based on the specific functions and material characteristics of the chip. The specific selection and design calculation methods adopt existing technologies in this field, so they will not be elaborated in detail.

### Embodiment 1

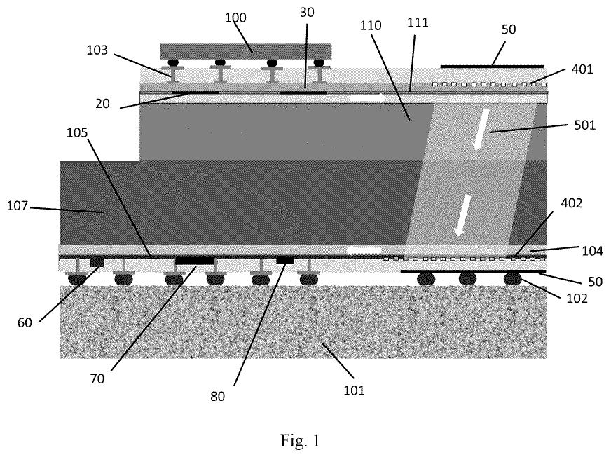

As shown in FIG. 1, it is a schematic diagram of heterogeneous integration and interconnection scheme based on optical TSV passing through InP and Si substrates. The structure from top to bottom is as follows: InP chip driver circuit board 100, electrical via 103, metal reflector 50, InP waveguide layer 111, InP substrate 110, silicon substrate 107, SiO₂ layer 104, silicon waveguide layer 105, metal reflector 50, solder ball array 102, and packaging substrate 101;

Among them, the InP waveguide layer 111 is equipped with a power monitor 20, a laser 30, and an InP chip side interlayer coupling grating 401. The silicon waveguide layer is equipped with a silicon optical chip side interlayer coupling grating 402, a high-speed modulator 80, a silicon waveguide device 70, and a high-speed detector 60.

In Embodiment 1, for optoelectronic chips on InP and Si substrates, a back-to-back coupling method is chosen, where the backside of the InP substrate and the backside of the Si substrate are in contact and bonded to each other.

Firstly, InP chips are fabricated on semi insulating or doped InP substrates using mature III-V semiconductor processes, including quantum well/quantum dot epitaxial growth, waveguide etching, interlayer coupling grating fabrication, SiO₂ insulation layer deposition, via window etching, metal electrode deposition, and other mature processes.

According to the functional requirements of the system, in addition to the laser, InP active devices can also include diode devices such as modulators, amplifiers, detectors, etc. The p and n electrodes are both made on the surface of the chip, so the commonly required ground electrode is not deposited on the back of the chip, allowing light to pass through the substrate. Metal electrodes are simultaneously deposited on the surface of the chip while reflecting metal mirrors are fabricated on top of the grating. Similarly, active and passive devices such as high-speed modulators, high-speed Ge/Si detectors, arrayed waveguide grating wavelength division multiplexing/routers, and interlayer coupling gratings are fabricated on the SOI wafer.

The polished backsides of the SOI chip and the InP chip are put in contact and bonded back-to-back, with interlayer grating-to-grating alignments for optical coupling, as shown in FIG. 1. One implementation method is to use molecular covalent bonding, where a layer of several nanometers thick SiO₂ may be deposited on the backside of the substrates of the Si and III-V chips. The two are then brought close together and bonded together by van der Waals forces between molecules. Adhesive bonding can also be used, using an organic compound such as DVS-BCB to bond the silicon chip and III-V chip together. Due to the bonding between two flat polished substrate backsides without any pattern processing on the surface, the bonding between them is stronger and more reliable than the traditional method of molecular bonding on the patterned front sides of the chips.

In this embodiment, the light emitted from the laser 30 in the InP chip and propagating along the InP waveguide is converted into a collimated beam that is emitted towards the substrate in a nearly vertical direction through the InP interlayer coupling grating 401. It then sequentially passes through the InP substrate 110 and the silicon substrate 107 of the SOI chip along the through-substrate via 501, and is interconnected through the interlayer coupling grating 402 on the SOI waveguide to the high-speed modulator 80, silicon waveguide device 70, and high-speed detector 60 on the SOI chip.

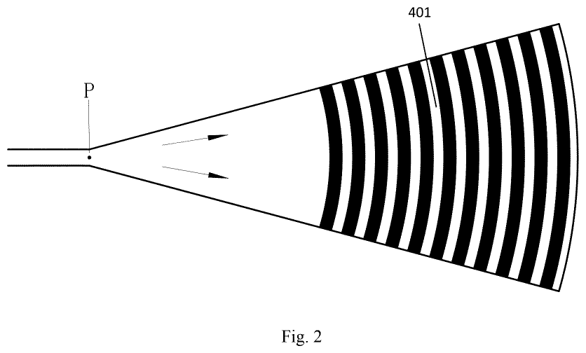

As shown in FIG. 2, the light emitted from the waveguide endpoint P through grating diffraction and finally transmitted to the optical through-substrate via is close to a collimated beam. By using the apodization method to design chirped collimating gratings, the grating etching depth and gradient duty cycle are optimized to obtain a gradient grating coupling coefficient. This ensures that the light emitted into the optical through-substrate via has a certain optical field distribution, resulting in a large and collimated beam size. As a result, a large alignment tolerance can be obtained, and passive alignment methods can be used for chip alignment.

Since part of the light is inevitably diffracted upward by the grating, to improve the efficiency of downward diffraction in the optical TSV configuration, we can conveniently deposit a high-reflection metal layer on the top of the grating at surface of the chip to avoid the more complex process of two-step etching required for a blazed echelle grating tooth profile, and improve the directionality and efficiency of the diffraction into the optical TSV. The high reflection metal film has a certain distance from the grating, so that the light directly diffracted by the chirped collimating grating to the optical through-substrate via interferes constructively with the light diffracted upward above the grating then reflected by the high reflection metal film to the optical through-substrate via, making the light transmitted to the optical through-substrate via the strongest.

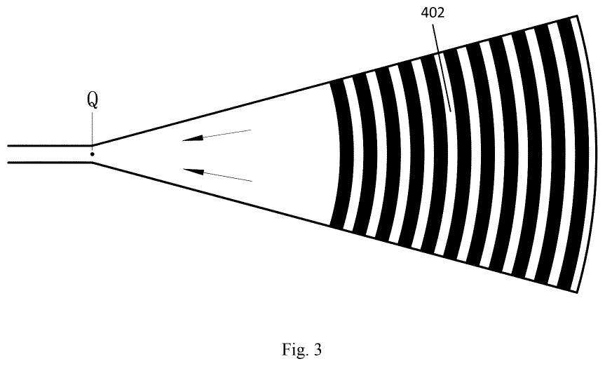

Similarly, we can design a chirped focusing coupling grating with a surface high-reflection metal film for the SOI waveguide plane. By optimizing the grating etching depth and the gradient duty cycle, we can obtain a gradient grating coupling coefficient to efficiently focus the incident collimated light onto the input port Q of the SOI modulator waveguide, as shown in FIG. 3. In addition, we can optimize the distance between the high reflection metal film and the grating, so that the light directly diffracted by the chirped focusing grating from the optical through-substrate via to the optical signal receiving point Q and the light reflected by the high reflection metal film and then diffracted by the chirped focusing grating to the optical signal receiving point can be interfered constructively, making the light coupled to the optical signal receiving point the strongest, thereby achieving efficient interlayer coupling and interconnection.

In the above embodiment, light is emitted from the waveguide endpoint P on the InP chip, diffracted by different grating teeth of the InP side interlayer coupling grating, and then transmitted to the optical through-substrate via. It is then diffracted by different grating teeth of the interlayer coupling grating on the silicon photonic chip side and reaches the focal point Q on the silicon photonic waveguide plane. The optical path difference between beams diffracted by different grating teeth is an integer multiple of the light wavelength.

### Embodiment 2

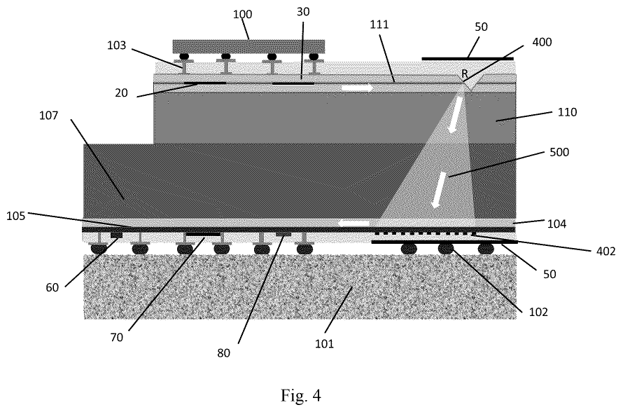

In the first embodiment described above, the InP chip side interlayer coupling grating 401 can be replaced by an InP chip side interlayer coupling reflection surface 400, as shown in FIG. 4. The InP chip side interlayer coupling reflection surface 400 can be fabricated by local wet chemical etching to obtain a smooth total reflection surface along a certain crystal direction angle. In this embodiment, the light emitted from the laser 30 in the InP chip and propagating along the InP waveguide is reflected by the InP interlayer coupling reflection surface 400 and then emitted towards the substrate through-substrate via 500 at a certain divergence angle. It sequentially passes through the InP substrate 110 and the silicon-based substrate 107 of the SOI chip along the through-substrate via, and then diffracts and focuses on the input port Q of the SOI waveguide through the interlayer coupling grating 402 on the SOI waveguide, as shown in FIG. 3. It is then interconnected to devices such as the high-speed modulator 80, silicon waveguide device 70, and high-speed detector 60 on the SOI chip. By designing the position of each grating tooth in the coupling grating 402 of the SOI waveguide plane, the optical path difference from the total reflection mirror R on the InP chip through the substrate via to the silicon photonic chip through different grating teeth, and then to the focal point Q on the silicon optical waveguide plane is an integer multiple of the optical wavelength. This enables the interlayer coupling grating to have chirping imaging function, that is, to image the total reflection mirror position R on the InP chip to the light entrance point Q of the optical waveguide on the silicon photonic chip. By optimizing the etching depth of the grating and the duty cycle variation, a gradient distribution of the grating coupling coefficient is obtained. In addition, the distance between the metal mirror 50 and the grating is optimized to ensure that the light directly diffracted from the optical through-substrate via through the chirped focusing grating to the optical signal receiving point Q and the light transmitted through the grating, reflected by the high reflectivity metal film, and then diffracted by the chirped imaging grating to the optical signal receiving point Q interfere constructively, making the light coupled to the optical signal receiving point the strongest, thereby achieving efficient interlayer coupling and interconnection.

### Embodiment 3

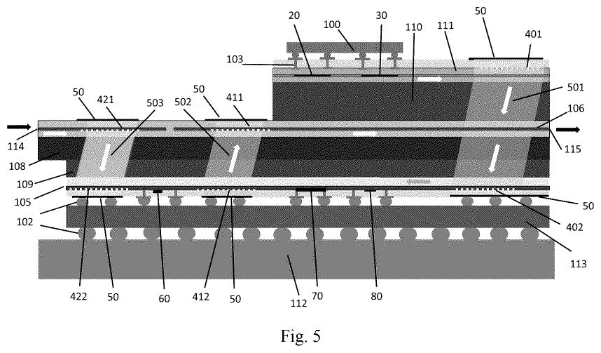

Due to the fact that SOI silicon photonic chips typically require processing node below 130 nm, the chip size based on precision stepper lithography is usually limited to 33 mm×26 mm mask area. To achieve larger or even wafer level on-chip systems, multiple reticles can be used for stitched exposures, but this will result in multiple photolithography steps. Additionally, due to the small size of SOI waveguides, stitching errors will lead to additional interconnect losses, making production difficult and reducing yield. Multiple sets of reticles will also lead to a significant increase in costs. To solve this problem, silicon-based Si₃N₄(abbreviated as SiN) or SiO₂ (PLC) passive waveguide platforms with simple processes can be used to achieve wafer level large-area optical interconnection, requiring only one or a few contact photolithography processes with low accuracy requirements. Contact lithography based PLC platforms or organic material optical backplane platforms can be used to significantly reduce costs. As shown in FIG. 5, a multi-layer stacked heterogeneous integration and interconnection scheme is provided based on three waveguide material platforms: InP, SiN, and SOI. The structure from top to bottom is as follows: driver circuit board 100 for InP chip, electrical via 103, metal mirror 50, InP waveguide layer 111, InP substrate 110, SiN waveguide 106, SiN wafer silicon substrate 108, SOI wafer silicon substrate 109, SiO₂ layer 104, silicon waveguide layer 105, metal mirror 50, solder ball array 102, intermediate transfer layer 113, solder ball array 102, motherboard PCB 112.

Among them, the InP waveguide layer includes a power monitor 20, a laser 30, and an InP chip side interlayer coupling grating 401. The SiN waveguide 106 is equipped with SiN passive waveguide devices and SiN waveguide interlayer coupling gratings. The silicon waveguide layer 105 includes a silicon photonic chip side interlayer coupling grating, a high-speed modulator 80, a silicon waveguide device 70, and a high-speed detector 60.

The SiN waveguide interlayer coupling grating includes SiN waveguide interlayer coupling grating 411 and SiN waveguide interlayer coupling grating 421, etc.

The silicon photonic chip side interlayer coupling grating includes silicon photonic chip side interlayer coupling grating one 402, silicon photonic chip side interlayer coupling grating two 412, silicon optical chip side interlayer coupling grating three 422, etc.

One end of the SiN waveguide layer is the optical signal input port 114, and the other end is the optical signal output port 115;

In the third embodiment of multi-layer stacking based on three waveguide material platforms, a large-area silicon-based SiN passive waveguide wafer will be used as an optical substrate, bonded back-to-back with active SOI silicon photonic chip through two silicon substrates, and interconnected through two interlayer coupling gratings on the SiN waveguide and the SOI waveguide. The substrate of the InP chip is bonded to the SiO₂ upper cladding layer flattened by chemical-mechanical polishing (CMP) on the front of the SiN waveguide wafer. The light emitted from the laser 30 in the InP chip and propagating along the InP waveguide is converted into a collimated beam that is emitted towards the substrate in a nearly vertical direction through the InP interlayer coupling grating 401. It sequentially passes through the InP substrate 110, SiN waveguide 106 and its Si substrate 108, and the Si substrate 109 of the SOI chip along the through-substrate via one 501, and then interconnects to the high-speed modulator 80, silicon waveguide device 70, and other devices on the SOI chip through the interlayer coupling grating 402 on the SOI waveguide. It is then diffracted by the interlayer coupling grating 412 on the silicon photonic chip side to pass through the Si substrate 109 of the SOI chip through the substrate via two 502, then through the Si substrate 108 of the SiN waveguide, and is then coupled to the SiN waveguide 106 through the interlayer coupling grating 411 on the SiN wafer, and finally transmit from port 115 to the on-chip remote node through the large-area multi-node interconnect network of the SiN waveguide layer.

Conversely, the optical signal transmitted by the remote node is incident from port 114 in the SiN waveguide layer 106, coupled through the interlayer coupling grating 421 on the SiN waveguide side to the through-substrate via three 503, sequentially passing through the Si substrate 108 of the SiN waveguide and the Si substrate 109 of the SOI chip, and then coupled to the high-speed detector 60 on the SOI chip through the interlayer coupling grating 422 on the SOI waveguide, which is then converted into an electrical signal. The propagation directions of optical signals within the multi-layer chip are indicated by the arrows. Each of the optical through-substrate via 501, 502, and 503 does not require the creation of physical boundaries that penetrate the substrate, but is defined by the design of interlayer couplers at both ends, which is easier to fabricate than electrical TSVs. The substrate of each wafer can be appropriately thinned as needed. SiN waveguide wafers can be coated with anti-reflective (AR) dielectric thin films before and after depositing the SiO₂ lower cladding layer, respectively, to reduce the reflection loss of interlayer interconnects. Passive components such as low loss and low crosstalk arrayed waveguide grating wavelength division multiplexers/routers, splitters, etc. can also be fabricated on the SiN waveguide layer as needed. The SiN waveguide can also be replaced by SiO₂ waveguide or organic material waveguide, and can also be directly fabricated on SOI chip wafers.

By using semi-insulating or undoped InP substrates and silicon substrates, the optical propagation loss of the optical through-substrate via of the present invention can achieve ultra-low loss. For example, the transmission loss of a semi-insulating InP substrate with a thickness of 600 microns measured in the experiment is only 0.3 dB. Due to the fact that the optical signal is emitted or incident from the substrate direction, it is easy to deposit a metal reflector film above the grating at the front surface of the chip, achieving efficient uni-directional coupling. Theoretically, the coupling grating loss after optimized design can be as low as 0.5 dB or less. Based on the principle of apodized imaging, the gradient grating coupling coefficient is obtained by optimizing the design of grating etching depth and gradient duty cycle. The diffraction light field on the grating, which originally decreases exponentially along the waveguide propagation direction, is cut into a shape close to Gaussian. When penetrating the substrate, it can be collimated and propagated in a conformal manner, with a diameter of up to tens of micrometers, thus obtaining a large alignment tolerance. Therefore, the present invention adopts a heterogeneously integrated optoelectronic chip based on optical through-substrate vias, and proposes an optical through-substrate via structure for 3D integration of multi-layer photonic chips for wafer level on-chip system applications, while solving the technical difficulties of silicon-based III-V heterogeneous integration and 3D multi-layer chip stacking. By utilizing advanced packaging technology for chiplet integration, the optical transceiver interconnect chip is integrated with GPU/NPU and other electronic chips at the wafer level. This not only integrates the electrical-to-optical and optical-to-electrical conversions of GPU/NPU I/O ports inside the photonic chip, but also greatly improves chip integration level and reduces the system size. Through the novel optical TSVs, optical signals pass through InP and Si substrates, achieving efficient and high tolerance optical coupling between III-V waveguide layers and SOI or SiN layers while avoiding flip-chip bonding between III-V chips and SiN/SOI chips. The front electrode layers of these two chips are left for electrical interconnection with electronic chips or RDL/PCB, thus avoiding the use of traditional electrical TSVs with high process difficulty on silicon photonic chips.

Finally, it should be noted that the above embodiments are only used to illustrate the technical solution of the present invention and not to limit it. Although the present invention has been described in detail with reference to the embodiments, those skilled in the art should understand that modifications or equivalent substitutions can still be made to the technical solutions of the present invention, and these modifications or equivalent substitutions cannot make the modified technical solutions deviate from the spirit and scope of the technical solutions of the present invention.

What is claimed is:

1. A heterogeneously integrated optoelectronic chip based on optical through-substrate via, characterized in that it comprises
multiple stacked optoelectronic chips based on the same or different types of substrates, each layer of optoelectronic chip is provided with several optoelectronic devices and optical waveguides, and at least one pair of optoelectronic chips of different layers are each provided with an interlayer coupling structure;
an optical through-substrate via between the interlayer coupling structures of the at least one pair of optoelectronic chips, wherein the first layer of optoelectronic chip and the second layer of optoelectronic chip in the at least one pair of optoelectronic chips are attached back-to-back, that is, the back of the first substrate and the back of the second substrate are in contact or bonded to each other and the optical through-substrate via passes through at least two substrates;
wherein the first interlayer coupling structure in the first layer of optoelectronic chip based on the first substrate converts the light propagating along the optical waveguide in the plane of the first layer of optoelectronic chip into light propagating along the optical through-substrate via in the first substrate through reflection or diffraction mechanism, the second interlayer coupling structure within the second layer of the optoelectronic chip based on the second substrate converts the light propagating along the optical through-substrate via in the second substrate into light propagating along the optical waveguide in the plane of the second optoelectronic chip layer through reflection or diffraction mechanisms;
wherein the front electrode of the first layer of optoelectronic chip is electrically connected to external circuits such as the electronic driver chip, and the front electrode of the second layer of optoelectronic chip is flip-chip bonded to an interposer to achieve high-speed electrical interconnection with electronic drivers, computing chips, and switching chips;
wherein the interlayer signal transmission is achieved through the optical through-substrate via, thereby avoiding the traditional difficult-to-fabricate electrical TSVs.

2. A heterogeneously integrated optoelectronic chip based on optical through-substrate via according to claim 1, characterized in that: the first layer optoelectronic chip based on the first substrate comprises at least one of optical signal emitting devices, optical amplification devices, optical modulators, optical detectors, and passive optical waveguide interconnect devices, and the interlayer coupling structure of said first layer of optoelectronic chip is a coupling grating or a reflection mirror composed of a tilted etched surface;
the second layer optoelectronic chip based on the second substrate comprises at least one of passive optical waveguide interconnect devices, optical modulators, and optical signal receivers, and the interlayer coupling structure of said second layer of the optoelectronic chip is a coupling grating or a reflection mirror composed of a tilted etched surface.

3. A heterogeneously integrated optoelectronic chip based on an optical through-substrate via according to claim 1, characterized in that the first layer of optoelectronic chip is back-to-back coupled with the second layer of optoelectronic chip, and the back of the first substrate is in contact or bonded with the back of the second substrate, wherein the contact surface of one or two substrates is smooth or coated with an optical anti-reflection film.

4. A heterogeneously integrated optoelectronic chip based on an optical through-substrate via according to claim 1, characterized in that: the back of the third substrate of the third layer of optoelectronic chip is in contact with the front of the first layer of optoelectronic chip, and the back of the third substrate is polished or coated with an optical anti-reflection film.

5. A heterogeneously integrated optoelectronic chip based on optical through-substrate vias according to claim 1, characterized in that the first substrate is InP, GaAs or compound semiconductor material, and the second substrate is Si, SiO2, quartz or organic substrate material.

6. A heterogeneously integrated optoelectronic chip based on an optical through-substrate via according to claim 1, characterized in that the first interlayer coupling structure is a chirped collimated grating, so that the light coupled to the optical through-substrate via is a parallel beam, and the gradient grating coupling coefficient is obtained by optimizing the design of grating etching depth and gradient duty cycle, so that the light emitted to the optical through-substrate via has a certain optical field distribution, trimming the diffracted light field on the grating that exponentially decreases along the waveguide propagation direction into a shape close to Gaussian, resulting in a large and collimated beam size, satisfying the conditions of large alignment tolerance and large coupling efficiency.

7. A heterogeneously integrated optoelectronic chip based on an optical through-substrate via according to claim 6, characterized in that: a layer of high reflection metal film is deposited on the upper surface of the chirped collimated grating as a metal reflector, and the high reflection metal film is at a certain distance from the grating, so that the light directly diffracted by the chirped collimated grating to the optical through-substrate via can be constructively interfered with the light diffracted upward above the grating and then reflected by the high reflection metal film to the optical through-substrate via, resulting in the highest light intensity transmitted to the optical through-substrate via.

8. A heterogeneously integrated optoelectronic chip based on an optical through-substrate via according to claim 1, characterized in that the first interlayer coupling structure is an etched surface placed at a specific angle, so that the light incident from the waveguide to the etched surface undergoes total reflection and propagates through the substrate.

9. A heterogeneously integrated optoelectronic chip based on an optical through-substrate via according to claim 1, characterized in that the second interlayer coupling structure is a chirped focusing grating, which focuses the optical signal received from the optical through-substrate via onto the optical signal receiving point on the second layer optoelectronic sub chip, and optimizes the grating etching depth and gradient duty cycle to achieve the highest receiving coupling efficiency.

10. A heterogeneously integrated optoelectronic chip based on optical through-substrate via according to claim 9, characterized in that: a layer of high reflection metal film is deposited on the surface of the chirped focusing grating cladding as a metal reflector, and the high reflection metal film is at a certain distance from the chirped focusing grating, so that the light directly diffracted from the optical through-substrate via to the optical signal receiving point by the chirped focusing grating is constructively interfered with the light transmitted through the grating, reflected by the high reflection metal film, and then diffracted by the chirped focusing grating to the optical signal receiving point, resulting in the strongest coupling of light to the optical signal receiving point.
